(19) United States
(12) Patent Application Publication
(10) Pub. No.: US 2026/0142652 A1
(43) Pub. Date: May 21, 2026

(54) OPERATING FREQUENCY REGULATION METHOD, OPERATING FREQUENCY CONTROL CIRCUIT, AND RADIO FREQUENCY POWER SUPPLY DEVICE

(71) Applicant: SHENZHEN RSPOWER TECHNOLOGY CO., LTD., Shenzhen (CN)

(72) Inventors: Shuxiao WANG, Shenzhen (CN); Yati CHEN, Shenzhen (CN)

(21) Appl. No.: 19/449,954

(22) Filed: Jan. 15, 2026

Related U.S. Application Data
(63) Continuation of application No. PCT/CN2024/116086, filed on Aug. 30, 2024.

(30) Foreign Application Priority Data
Dec. 20, 2023 (CN) 202311754223.2

(51) Int. Cl. H03K 5/04

(52) U.S. Cl. CPC H03K 5/04

(57) ABSTRACT

An operating frequency regulation method for a radio frequency (RF) circuit, an operating frequency control circuit, and an RF power supply device are provided. The operating frequency regulation method for the RF circuit includes the following. The RF circuit is controlled to output to a load at different operating frequencies. A circuit parameter of the RF circuit during output of the RF circuit at each of the different operating frequencies is detected. A resonant frequency of the RF circuit is calculated based on the detected circuit parameter of the RF circuit during the output of the RF circuit at each of the different operating frequencies. An operating frequency of the RF circuit is regulated to the resonant frequency.

### CROSS-REFERENCE TO RELATED APPLICATION(S)

This application is a continuation of International Application No. PCT/CN2024/116086, filed Aug. 30, 2024, which claims priority to Chinese Patent Application No. 202311754223.2, filed Dec. 20, 2023, the entire disclosure of which are hereby incorporated by reference.

### TECHNICAL FIELD

This disclosure relates to the field of radio frequency (RF) technologies, in particular, to an operating frequency regulation method for an RF circuit, an operating frequency control circuit, and an RF power supply device.

### BACKGROUND

At present, with the popularization of various applications of radio frequency (RF), RF circuits have been increasingly applied in various fields. An operating frequency of an RF circuit is particularly important for an output of the RF circuit, and operating at a resonant frequency of the RF circuit can achieve good effect.

### SUMMARY

In a first aspect, an operating frequency regulation method for a radio frequency (RF) circuit is provided. The operating frequency regulation method for the RF circuit includes the following. The RF circuit is controlled to output to a load at different operating frequencies. A circuit parameter of the RF circuit during output of the RF circuit at each of the different operating frequencies is detected. A resonant frequency of the RF circuit is calculated based on the detected circuit parameter of the RF circuit during the output of the RF circuit at each of the different operating frequencies. An operating frequency of the RF circuit is regulated to the resonant frequency.

In a second aspect, an operating frequency control circuit is further provided. The operating frequency control circuit is configured to regulate an operating frequency of an RF circuit, and includes a control unit and a circuit parameter detection unit. The control unit is configured to control the RF circuit to output to a load at different operating frequencies. The circuit parameter detection unit is configured to detect a circuit parameter of the RF circuit during output of the RF circuit at each of the different operating frequencies. The control unit is further configured to calculate a resonant frequency of the RF circuit based on the detected circuit parameter of the RF circuit during the output of the RF circuit at each of the different operating frequencies, and control to regulate the operating frequency of the RF circuit to the resonant frequency.

In a third aspect, an RF power supply device is further provided. The RF power supply device includes the above operating frequency control circuit and an RF circuit. The operating frequency control circuit is configured to control operations in the above operating frequency regulation method for the RF circuit to be performed to regulate an operating frequency of the RF circuit. The RF circuit has a resonant frequency f₀, and includes an RF power supply and an RF output end. The RF power supply is configured to output to a load at different operating frequencies. The RF output end is configured to be connected to the load. The operating frequency control circuit includes a control unit and a circuit parameter detection unit. The control unit is configured to control the RF circuit to output to a load at different operating frequencies. The circuit parameter detection unit is configured to detect a circuit parameter of the RF circuit during output of the RF circuit at each of the different operating frequencies. The control unit is further configured to calculate a resonant frequency of the RF circuit based on the detected circuit parameter of the RF circuit during the output of the RF circuit at each of the different operating frequencies, and control to regulate the operating frequency of the RF circuit to the resonant frequency. The operating frequency regulation method for the RF circuit includes the following. The RF circuit is controlled to output to a load at different operating frequencies. A circuit parameter of the RF circuit during output of the RF circuit at each of the different operating frequencies is detected. A resonant frequency of the RF circuit is calculated based on the detected circuit parameter of the RF circuit during the output of the RF circuit at each of the different operating frequencies. An operating frequency of the RF circuit is regulated to the resonant frequency.

### BRIEF DESCRIPTION OF THE DRAWINGS

In order to describe technical solutions in embodiments of the disclosure or the related art more clearly, the following will give an introduction to accompanying drawings required for describing the embodiments of the disclosure or the related art.

FIG. 1 is a flowchart of an operating frequency regulation method for a radio frequency (RF) circuit in an embodiment of the disclosure.

FIG. 2 is a flowchart of an operating frequency regulation method for an RF circuit in another embodiment of the disclosure.

FIG. 3 is a flowchart of an operating frequency regulation method for an RF circuit in yet another embodiment of the disclosure.

FIG. 4 is a flowchart of an operating frequency regulation method for an RF circuit in still another embodiment of the disclosure.

FIG. 5 is a schematic structural diagram of an operating frequency control circuit in an embodiment of the disclosure.

FIG. 6 is a schematic structural diagram of an RF power supply device in an embodiment of the disclosure.

FIG. 7 is a schematic circuit diagram of an RF power supply device in an embodiment of the disclosure.

Description of reference signs of the accompanying drawings:
1—RF power supply device; 10—operating frequency control circuit; 110—control unit; 120—circuit parameter detection unit; 20—RF circuit; 210—RF power supply; 220—RF output end; 230—inductor-capacitor network; L1—equivalent inductor; C1—equivalent capacitor; U—output voltage value; I—current value; RL—load; GND—ground.

### DETAILED DESCRIPTION

Technical solutions in embodiments of the disclosure will be clearly and completely described below with reference to accompanying drawings in embodiments of the disclosure. Apparently, embodiments described herein are merely some embodiments, rather than all embodiments, of the disclosure. Based on the embodiments of the disclosure, all other embodiments obtained by those of ordinary skill in the art without creative effort shall fall within the protection scope of the disclosure.

In the description of embodiments of the disclosure, it may be noted that the orientation or positional relations indicated by terms such as “inner”, “outer”, etc., are orientation or positional relations based on the accompanying drawings, only for facilitating the description of the disclosure and simplifying the description, rather than indicating or implying that the referred devices or elements must be in a particular orientation or constructed or operated in the particular orientation, and therefore they may not be construed as limiting the disclosure.

In the description of embodiments of the disclosure, it may be noted that unless specified or limited otherwise, terms “connected” and “coupled” should be understood in a broad sense. For example, coupling may be a fixed coupling, a detachable coupling, or an integrated coupling; may be a mechanical coupling or an electrical coupling; and may be a direct coupling or an indirect coupling through an intermediate medium. For those of ordinary skill in the art, the specific meanings of the above terms in the disclosure can be understood in specific cases.

In the description of embodiments of the disclosure, it may be noted that terms “first”, “second”, and the like in the specification, claims, and accompanying drawings of the disclosure are used to distinguish similar objects rather than describe a particular order or a precedence order. It may be understood that, the data used that way may be interchangeable where appropriate, so that the embodiments of the disclosure described herein can be implemented in sequences other than those illustrated or described herein.

In addition, the terms “include”, “comprise”, and “have” as well as variations thereof are intended to cover non-exclusive inclusion. For example, a procedure, a method, a system, a product, or a server that includes a series of operations or units is not necessarily limited to those operations or units that are listed explicitly, but may include other operations or units that are not listed explicitly or include other operations or units that are inherent to such a procedure, a method, a product, or a device.

At present, with the popularization of various applications of radio frequency (RF), RF circuits have been increasingly applied in various fields. An operating frequency of an RF circuit is particularly important for an output of the RF circuit, and operating at a resonant frequency of the RF circuit can achieve good effect. However, the design of an existing RF circuit is becoming more complex, with a greater diversity of components. Adjusting the RF circuit by adjusting values of components such as an inductor and a capacitor of the RF circuit becomes particularly difficult, and it is still difficult to determine the resonant frequency of the RF circuit through multiple tests.

Therefore, how to quickly determine the resonant frequency of the RF circuit and regulate the operating frequency of the RF circuit to the resonant frequency becomes a problem to be considered.

An operating frequency regulation method for an RF circuit, an operating frequency control circuit, and an RF power supply device are provided in the disclosure, which can quickly determine a resonant frequency of the RF circuit and regulate an operating frequency of the RF circuit to the resonant frequency.

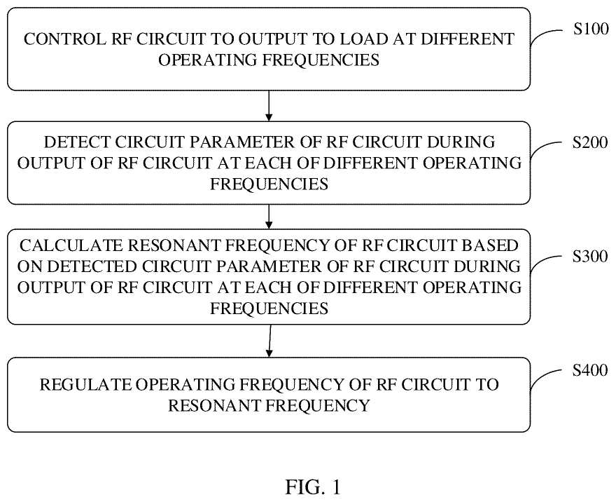

Reference can be made to FIG. 1, where FIG. 1 is a flowchart of an operating frequency regulation method for an RF circuit in an embodiment of the disclosure. As illustrated in FIG. 1, an operating frequency regulation method for an RF circuit is provided in the disclosure. The operating frequency regulation method for the RF circuit includes the following.

At S100, the RF circuit is controlled to output to a load at different operating frequencies.

At S200, a circuit parameter of the RF circuit during output of the RF circuit at each of the different operating frequencies is detected.

At S300, a resonant frequency of the RF circuit is calculated based on the detected circuit parameter of the RF circuit during the output of the RF circuit at each of the different operating frequencies.

At S400, an operating frequency of the RF circuit is regulated to the resonant frequency.

As such, based on the above operating frequency regulation method for the RF circuit in the disclosure, the resonant frequency of the RF circuit can be quickly determined based on the circuit parameter of the RF circuit during output of the RF circuit at each operating frequency, and the operating frequency of the RF circuit can be regulated to the resonant frequency.

At present, values of components such as an inductor and a capacitor of the RF circuit need to be determined to calculate a resonant frequency, or the values of the components such as the inductor and the capacitor of the RF circuit may be adjusted to determine whether a maximum output power is reached. In contrast, according to the operating frequency regulation method in the disclosure, regardless of the complexity of the design of the RF circuit, the resonant frequency of the RF circuit can be calculated based on the circuit parameter of the RF circuit during the output of the RF circuit at each operating frequency. In this way, without a need to determine the values of the components such as the inductor and the capacitor of the RF circuit one by one and adjust the values of the components such as the inductor and the capacitor of the RF circuit, the resonant frequency of the RF circuit can be determined, and thus the calculation is simple and more efficient.

In one or more embodiments, when a duration of output of the RF circuit at the resonant frequency reaches a preset duration, the above operations at S100 to S400 can be re-performed on the RF circuit, so as to avoid a decrease in an output power due to the fact that the resonant frequency of the RF circuit changes but the operating frequency of the RF circuit is not regulated for a long time.

When the duration of the output of the RF circuit at the resonant frequency reaches the preset duration, a circuit parameter of the RF circuit during output of the RF circuit at the resonant frequency may be further detected, and whether to re-perform the above operations at S100 to S400 on the RF circuit may be determined based on the detected circuit parameter of the RF circuit during the output of the RF circuit at the resonant frequency, so that the above operations at S100 to S400 are performed when the resonant frequency of the RF circuit needs to be re-determined.

The circuit parameter may at least include a current value I of the RF circuit during the output of the RF circuit at the resonant frequency. By determining an initial phase angle of the current value I, when the initial phase angle is not zero, the above operations at S100 to S400 are re-performed on the RF circuit.

In one or more embodiments, when a load connected to the RF circuit changes, the above operations at S100 to S400 can be re-performed on the RF circuit, so as to avoid a decrease in an output power due to the fact that the resonant frequency of the RF circuit changes with the change of the load but the operating frequency of the RF circuit is not regulated.

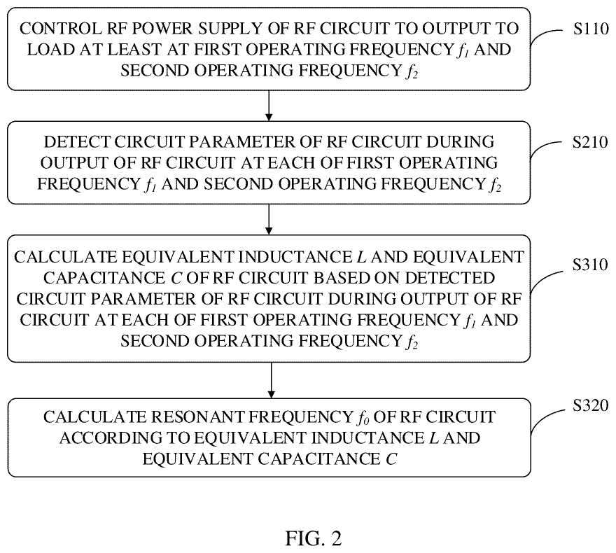

Reference can be made to FIG. 2, where FIG. 2 is a flowchart of an operating frequency regulation method for an RF circuit in another embodiment of the disclosure. The RF circuit includes an RF power supply. As illustrated in FIG. 2, for S100, the RF circuit is controlled to output to the load at the different operating frequencies as follows.

At S110, the RF power supply of the RF circuit is controlled to output to the load at least at a first operating frequency f₁ and a second operating frequency f₂.

As such, the resonant frequency of the RF circuit can be determined simply by controlling the RF power supply of the RF circuit to output to the load at least at the first operating frequency f₁ and the second operating frequency f₂.

As illustrated in FIG. 2, for S200, the circuit parameter of the RF circuit during the output of the RF circuit at each of the different operating frequencies is detected as follows.

At S210, a circuit parameter of the RF circuit during output of the RF circuit at each of the first operating frequency f₁ and the second operating frequency f₂ is detected.

As such, by detecting the circuit parameter of the RF circuit during the output of the RF circuit at each of the first operating frequency f₁ and the second operating frequency f₂, the resonant frequency of the RF circuit can be calculated.

As illustrated in FIG. 2, for S300, the resonant frequency of the RF circuit is calculated based on the detected circuit parameter of the RF circuit during the output of the RF circuit at each of the different operating frequencies as follows.

At S310, an equivalent inductance L and an equivalent capacitance C of the RF circuit are calculated based on the detected circuit parameter of the RF circuit during the output of the RF circuit at each of the first operating frequency f₁ and the second operating frequency f₂.

At S320, the resonant frequency f₀ of the RF circuit is calculated according to the equivalent inductance L and the equivalent capacitance C.

As such, the equivalent inductance L and the equivalent capacitance C of the RF circuit can be calculated simply based on the detected circuit parameter of the RF circuit during the output of the RF circuit at each of the first operating frequency f₁ and the second operating frequency f₂, and then the resonant frequency f₀ of the RF circuit is also obtained.

Specifically, if values of components such as an inductor and a capacitor of the RF circuit are not adjusted, the resonant frequency of the RF circuit generally does not change. However, if the values of the components such as the inductor and the capacitor of the RF circuit are determined one by one, or the values of the components such as the inductor and the capacitor of the RF circuit are adjusted, the complex calculation, an increase in the number of tests, and an increase in the difficulty of tests may usually occur. In contrast, according to the operating frequency regulation method in the disclosure, the equivalent inductance L and the equivalent capacitance C of the RF circuit can be calculated simply based on the detected circuit parameter of the RF circuit during the output of the RF circuit at each of the first operating frequency f₁ and the second operating frequency f₂, and then the resonant frequency f₀ of the RF circuit is also obtained.

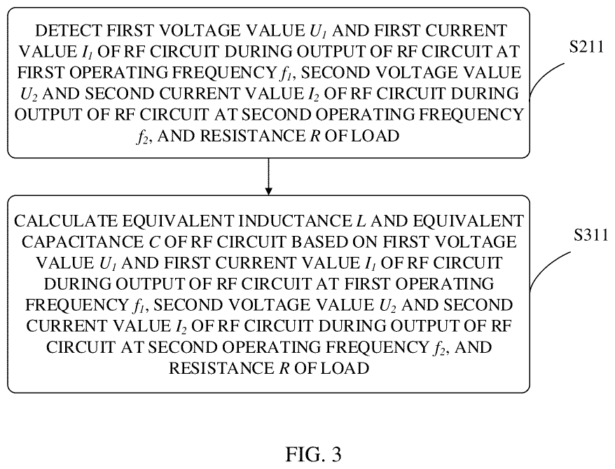

Reference can be made to FIG. 3, where FIG. 3 is a flowchart of an operating frequency regulation method for an RF circuit in yet another embodiment of the disclosure. As illustrated in FIG. 2 and FIG. 3, for S210, the circuit parameter of the RF circuit during the output of the RF circuit at each of the first operating frequency f₁ and the second operating frequency f₂ is detected as follows.

At S211, a first voltage value U₁ and a first current value I₁ of the RF circuit during output of the RF circuit at the first operating frequency f₁, a second voltage value U₂ and a second current value I₂ of the RF circuit during output of the RF circuit at the second operating frequency f₂, and a resistance R of the load are detected.

The first voltage value U₁ is an output voltage value U of the RF power supply during output of the RF power supply at the first operating frequency f₁, the second voltage value U₂ is an output voltage value U of the RF power supply during output of the RF power supply at the second operating frequency f₂, the first current value I₁ is a current value I of the RF circuit during the output of the RF circuit at the first operating frequency f₁, and the second current value I₂ is a current value I of the RF circuit during the output of the RF circuit at the second operating frequency f₂.

As such, by detecting an output voltage value U of the RF power supply during output of the RF power supply at each of the first operating frequency f₁ and the second operating frequency f₂, a current value I of the RF circuit during the output of the RF circuit at each of the first operating frequency f₁ and the second operating frequency f₂, and the resistance R of the load, a resonant frequency of a complex RF circuit can be obtained simply by detecting several circuit parameters of the RF circuit.

As illustrated in FIG. 2 and FIG. 3, for S310, the equivalent inductance L and the equivalent capacitance C of the RF circuit are calculated based on the detected circuit parameter of the RF circuit during the output of the RF circuit at each of the first operating frequency f₁ and the second operating frequency f₂ as follows.

At S311, the equivalent inductance L and the equivalent capacitance C of the RF circuit are calculated, based on the first voltage value U₁ and the first current value I₁ of the RF circuit during the output of the RF circuit at the first operating frequency f₁, the second voltage value U₂ and the second current value I₂ of the RF circuit during the output of the RF circuit at the second operating frequency f₂, and the resistance R of the load.

As such, the equivalent inductance L and the equivalent capacitance C of the RF circuit can be calculated according to the first voltage value U₁, the first current value I₁, the second voltage value U₂, the second current value 12, and the resistance R of the load.

It may be noted that, regardless of components included in the RF circuit, if values of components such as an inductor and a capacitor of the RF circuit are not adjusted, the RF circuit has a substantially constant resonant frequency, and thus also has an equivalent inductance L and an equivalent capacitance C. The equivalent inductance L and the equivalent capacitance C may originate from the components such as the inductor and the capacitor of the RF circuit, or may originate from the RF power supply in the RF circuit or the load outside the RF circuit, or may be only a parasitic inductance and a parasitic capacitance of the RF circuit.

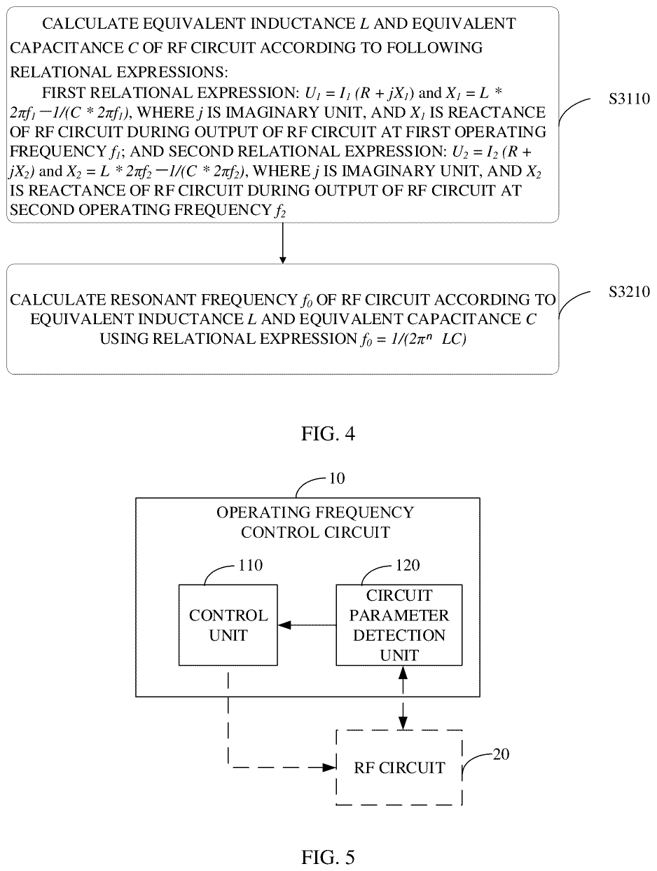

Reference can be made to FIG. 4, where FIG. 4 is a flowchart of an operating frequency regulation method for an RF circuit in still another embodiment of the disclosure. As illustrated in FIG. 3 and FIG. 4, for S311, the equivalent inductance L and the equivalent capacitance C of the RF circuit are calculated, based on the first voltage value U₁ and the first current value I₁ of the RF circuit during the output of the RF circuit at the first operating frequency f₁, the second voltage value U₂ and the second current value I₂ of the RF circuit during the output of the RF circuit at the second operating frequency f₂, and the resistance R of the load as follows.

At S3110, the equivalent inductance L and the equivalent capacitance C of the RF circuit are calculated according to the following relational expressions: a first relational expression: U₁=I₁(R+jX₁) and X₁=L*2πf₁−1/(C*2πf₁), where j is an imaginary unit, and X₁ is a reactance of the RF circuit during the output of the RF circuit at the first operating frequency f₁; and a second relational expression: U₂=I₂(R+jX₂) and X₂=L*2πf₂−1/(C*2πf₂), where j is an imaginary unit, and X₂ is a reactance of the RF circuit during the output of the RF circuit at the second operating frequency f₂.

As such, by simultaneously solving the first relational expression and the second relational expression, two unknowns in the relational expressions, i.e., the equivalent inductance L and the equivalent capacitance C of the RF circuit, can be obtained.

As illustrated in FIG. 2, FIG. 3, and FIG. 4, for S320, the resonant frequency f₀ of the RF circuit is calculated according to the equivalent inductance L and the equivalent capacitance C as follows.

At S3210, the resonant frequency f₀ of the RF circuit is calculated according to the equivalent inductance L and the equivalent capacitance C using a relational expression

$${f}_{0} = 1 / ( 2 π \sqrt{LC} ) .$$

As such, in the case where the equivalent inductance L and the equivalent capacitance C of the RF circuit are obtained, the resonant frequency f₀ of the RF circuit can also be calculated.

According to the operating frequency regulation method for the RF circuit in the disclosure, through the above operations, regardless of the complexity of the design of the RF circuit, the resonant frequency of the RF circuit can be calculated based on the circuit parameter of the RF circuit during the output of the RF circuit at each operating frequency. In this way, without a need to determine the values of the components such as the inductor and the capacitor of the RF circuit one by one and adjust the values of the components such as the inductor and the capacitor of the RF circuit, and with only a need to control the RF power supply of the RF circuit to output to the load at least at the first operating frequency f₁ and the second operating frequency f₂, the equivalent inductance L and the equivalent capacitance C of the RF circuit can be calculated, and then the resonant frequency f₀ of the RF circuit can be also obtained.

Reference can be made to FIG. 5, where FIG. 5 is a schematic structural diagram of an operating frequency control circuit in an embodiment of the disclosure. As illustrated in FIG. 5, an operating frequency control circuit 10 is further provided in the disclosure. The operating frequency control circuit 10 is configured to regulate an operating frequency of an RF circuit 20, and includes a control unit 110 and a circuit parameter detection unit 120. The control unit 110 is configured to control the RF circuit 20 to output to a load RL at different operating frequencies. The circuit parameter detection unit 120 is configured to detect a circuit parameter of the RF circuit 20 during output of the RF circuit 20 at each of the different operating frequencies. The control unit 110 is further configured to calculate a resonant frequency of the RF circuit 20 based on the detected circuit parameter of the RF circuit 20 during the output of the RF circuit 20 at each of the different operating frequencies, and control to regulate the operating frequency of the RF circuit 20 to the resonant frequency.

As such, the control unit 110 can quickly determine the resonant frequency of the RF circuit 20 based on the circuit parameter of the RF circuit 20 during output of the RF circuit 20 at each operating frequency detected by the circuit parameter detection unit 120, and regulate the operating frequency of the RF circuit 20 to the resonant frequency.

In one or more embodiments, the control unit 110 is configured to control an RF power supply 210 of the RF circuit 20 to output to the load RL at least at a first operating frequency f₁ and a second operating frequency f₂. The circuit parameter of the RF circuit 20 during the output of the RF circuit 20 at each operating frequency at least includes a first voltage value U₁ and a first current value I₁ of the RF circuit 20 during output of the RF circuit 20 at the first operating frequency f₁, a second voltage value U₂ and a second current value I₂ of the RF circuit 20 during output of the RF circuit 20 at the second operating frequency f₂, and a resistance R of the load RL. The circuit parameter detection unit 120 is configured to detect the first voltage value U₁ and the first current value I₁ of the RF circuit 20 during the output of the RF circuit 20 at the first operating frequency f₁, the second voltage value U₂ and the second current value I₂ of the RF circuit 20 during the output of the RF circuit 20 at the second operating frequency f₂, and the resistance R of the load RL. The first voltage value U₁ is an output voltage value U of the RF power supply 210 during output of the RF power supply 210 at the first operating frequency f₁, the second voltage value U₂ is an output voltage value U of the RF power supply 210 during output of the RF power supply 210 at the second operating frequency f₂, the first current value I₁ is a current value I of the RF circuit 20 during the output of the RF circuit 20 at the first operating frequency f₁, and the second current value I₂ is a current value I of the RF circuit 20 during the output of the RF circuit 20 at the second operating frequency f₂.

When the control unit 110 controls the RF power supply 210 of the RF circuit 20 to output to the load RL at least at the first operating frequency f₁ and the second operating frequency f₂, a load RL with a standard resistance of 50Ω can be directly used. In this case, the circuit parameter detection unit 120 only needs to detect once whether the resistance of the load RL is 50Ω, to calculate an equivalent inductance L and an equivalent capacitance C of the RF circuit 20 by substituting the resistance of the load RL into the following relational expressions, which is more convenient for the detection and calculation.

In one or more embodiments, the control unit 110 is further configured to calculate an equivalent inductance L and an equivalent capacitance C of the RF circuit 20 based on a circuit parameter of the RF circuit 20 during output of the RF circuit 20 at each of the first operating frequency f₁ and the second operating frequency f₂, and then calculate the resonant frequency f₀ of the RF circuit 20 according to the equivalent inductance L and the equivalent capacitance C.

The control unit 110 is configured to calculate the equivalent inductance L and the equivalent capacitance C of the RF circuit 20 according to the following relational expressions: a first relational expression: U₁=I₁(R+jX₁) and X₁=L*2πf₁−1/(C*2πf₁), where j is an imaginary unit, and X₁ is a reactance of the RF circuit 20 during the output of the RF circuit 20 at the first operating frequency f₁; and a second relational expression: U₂=I₂(R+jX₂) and X₂=L*2πf₂−1/(C*2πf₂), where j is an imaginary unit, and X₂ is a reactance of the RF circuit 20 during the output of the RF circuit 20 at the second operating frequency f₂.

Then, the control unit 110 is configured to calculate the resonant frequency f₀ of the RF circuit 20 according to the equivalent inductance L and the equivalent capacitance C using a relational expression f₀=1/(2π\sqrt{LC}).

In one or more embodiments, the circuit parameter detection unit 120 may include a voltage detection unit, a current detection unit, and the like. The voltage detection unit may be a voltmeter, or may be other voltage detection devices such as a voltage sensor, or may be a voltage detection circuit composed of components such as a resistor, a capacitor, and a diode. The current detection unit may be an ammeter, or may be other current detection devices such as a Hall sensor, or may be a current detection circuit composed of components such as a resistor, a capacitor, and a diode.

In one or more embodiments, the control unit 110 may be a general-purpose processor such as a central processing unit (CPU), or may be a digital signal processor (DSP), an application-specific integrated circuit (ASIC), a field-programmable gate array (FPGA), or other programmable logic components, discrete gate logic components, transistor logic components, and the like. The control unit 110 may also be a microprocessor such as a micro control unit (MCU).

According to the operating frequency regulation method for the RF circuit 20 and the operating frequency control circuit 10 in the disclosure, through the above operations, regardless of the complexity of the design of the RF circuit 20, the control unit 110 can calculate the resonant frequency of the RF circuit 20 based on the circuit parameter of the RF circuit 20 during the output of the RF circuit 20 at each operating frequency detected by the circuit parameter detection unit 120. In this way, without a need to determine values of components such as an inductor and a capacitor of the RF circuit 20 one by one and adjust the values of the components such as the inductor and the capacitor of the RF circuit 20, and with only a need for the control unit 110 to control the RF power supply 210 of the RF circuit 20 to output to the load RL at least at the first operating frequency f₁ and the second operating frequency f₂, the equivalent inductance L and the equivalent capacitance C of the RF circuit 20 can be calculated, and then the resonant frequency f₀ of the RF circuit 20 can be also obtained.

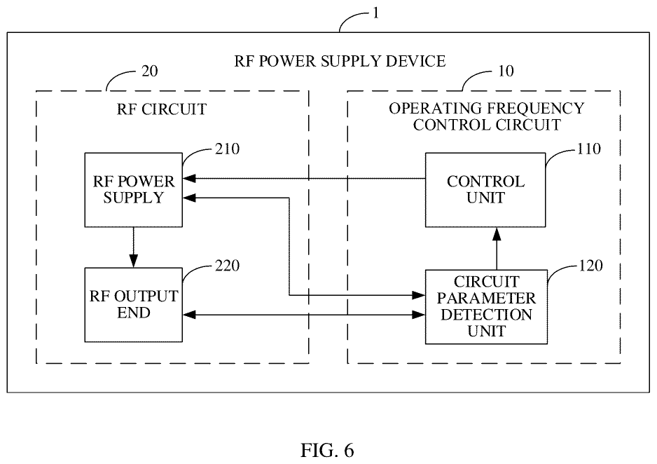

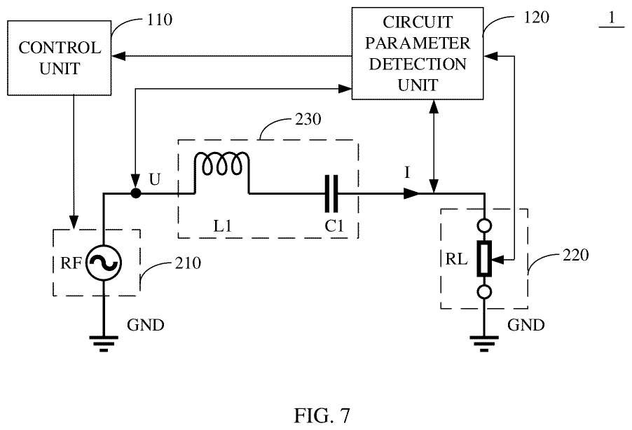

Reference can be made to FIG. 6 and FIG. 7, where FIG. 6 is a schematic structural diagram of an RF power supply device in an embodiment of the disclosure, and FIG. 7 is a schematic circuit diagram of an RF power supply device in an embodiment of the disclosure. As illustrated in FIG. 6 and FIG. 7, an RF power supply device 1 is further provided in the disclosure, and the RF power supply device 1 includes the above operating frequency control circuit 10 and an RF circuit 20. The operating frequency control circuit 10 is configured to control operations in the above operating frequency regulation method for the RF circuit 20 to be performed to regulate an operating frequency of the RF circuit 20. The RF circuit 20 has a resonant frequency f₀, and the RF circuit 20 includes an RF power supply 210 and an RF output end 220. The RF power supply 210 is configured to output to a load RL at different operating frequencies. The RF output end 220 is configured to be connected to the load RL.

As illustrated in FIG. 5, the operating frequency control circuit 10 includes a control unit 110 and a circuit parameter detection unit 120. The control unit 110 is configured to control the RF circuit 20 to output to a load RL at different operating frequencies. The circuit parameter detection unit 120 is configured to detect a circuit parameter of the RF circuit 20 during output of the RF circuit 20 at each of the different operating frequencies. The control unit 110 is further configured to calculate a resonant frequency of the RF circuit 20 based on the detected circuit parameter of the RF circuit 20 during the output of the RF circuit 20 at each of the different operating frequencies, and control to regulate the operating frequency of the RF circuit 20 to the resonant frequency.

As illustrated in FIG. 1, the operating frequency regulation method for the RF circuit includes the following.

At S100, the RF circuit is controlled to output to a load at different operating frequencies.

At S200, a circuit parameter of the RF circuit during output of the RF circuit at each of the different operating frequencies is detected.

At S300, a resonant frequency of the RF circuit is calculated based on the detected circuit parameter of the RF circuit during the output of the RF circuit at each of the different operating frequencies.

At S400, an operating frequency of the RF circuit is regulated to the resonant frequency.

For a specific structure of the operating frequency control circuit 10, reference can be made to the related content of the operating frequency control circuit 10 in any one of the above embodiments. For specific operations of the operating frequency regulation method for the RF circuit, reference can be made to the related content of the operating frequency regulation method for the RF circuit in any one of the above embodiments, which will not be repeated herein.

As such, the control unit 110 can quickly determine the resonant frequency of the RF circuit 20 based on the circuit parameter of the RF circuit 20 during output of the RF circuit 20 at each operating frequency detected by the circuit parameter detection unit 120, and regulate the operating frequency of the RF circuit 20 to the resonant frequency.

As illustrated in FIG. 7, the RF circuit 20 may further include an inductor-capacitor network, and the inductor-capacitor network includes at least one equivalent inductor L1 and at least one equivalent capacitor C1. The at least one equivalent inductor L1 and the at least one equivalent capacitor C1 are connected in series or in parallel.

It may be noted that, the RF circuit 20 may perform impedance matching, and in this case, the inductor-capacitor network 230 may be configured for impedance matching between an internal impedance of the RF power supply 210 and an impedance of the load RL. Alternatively, the RF circuit 20 may not perform impedance matching. An equivalent inductor L1 and an equivalent capacitor C1 in the inductor-capacitor network 230 illustrated in FIG. 7 merely indicate that the RF power supply 210 in the RF circuit 20 or the load RL outside the RF circuit 20 has an equivalent inductance L which is equal to an inductance of the equivalent inductor L1 and an equivalent capacitance C which is equal to a capacitance of the equivalent capacitor C1, or merely indicate that a parasitic inductance and a parasitic capacitance of the RF circuit 20 are respectively equivalent to the inductance of the equivalent inductor L1 and the capacitance of the equivalent capacitor C1.

In one or more embodiments, the circuit parameter detection unit 120 may detect an output voltage value U of the RF power supply 210 of the RF circuit 20 during output of the RF circuit 20 at each of a first operating frequency f₁ and a second operating frequency f₂, and a current value I of the RF circuit 20 during the output of the RF circuit 20 at each of the first operating frequency f₁ and the second operating frequency f₂ as illustrated in FIG. 7. The current value I of the RF circuit 20 is a main circuit current value of the RF circuit 20. That is, the RF circuit 20 as illustrated in FIG. 7 includes the RF power supply 210, the inductor-capacitor network 230, and the RF output end 220 which are connected in series, and in this case, the circuit parameter detection unit 120 may also detect a current value I of the RF circuit 20 between the RF power supply 210 and the inductor-capacitor network 230 or a current value I of the RF circuit 20 at another position, where each current value I is a main circuit current value of the RF circuit 20, and the disclosure is not limited in this regard.

In one or more embodiments, one end of the RF power supply 210 is connected to one end of the RF output end 220 or the inductor-capacitor network 230, and the other end of the RF power supply 210 may be connected to a ground GND.

According to the operating frequency regulation method for the RF circuit 20, the operating frequency control circuit 10, and the RF power supply device 1 in the disclosure, through the above operations and structures, regardless of the complexity of the design of the RF circuit 20, the control unit 110 can calculate the resonant frequency of the RF circuit 20 based on the circuit parameter of the RF circuit 20 during the output of the RF circuit 20 at each operating frequency detected by the circuit parameter detection unit 120. In this way, without a need to determine values of components such as an inductor and a capacitor of the RF circuit 20 one by one and adjust the values of the components such as the inductor and the capacitor of the RF circuit 20, and with only a need for the control unit 110 to control the RF power supply 210 of the RF circuit 20 to output to the load RL at least at the first operating frequency f₁ and the second operating frequency f₂, the equivalent inductance L and the equivalent capacitance C of the RF circuit 20 can be calculated, and then the resonant frequency f₀ of the RF circuit 20 can be also obtained.

The above descriptions are only the specific implementations of the disclosure, but the protection scope of the disclosure is not limited to the above. Any skilled in the technical field can easily think of changes or replacements within the technical scope of the disclosure, and the changes or replacements should be covered in the protection scope of the disclosure. The embodiments of the disclosure and features in the embodiments may be mutually combined without conflicts. Therefore, the protection scope of the disclosure shall be subject to the protection scope of the claims.

What is claimed is:

1. An operating frequency regulation method for a radio frequency (RF) circuit, comprising:
controlling the RF circuit to output to a load at different operating frequencies;
detecting a circuit parameter of the RF circuit during output of the RF circuit at each of the different operating frequencies;
calculating a resonant frequency of the RF circuit based on the detected circuit parameter of the RF circuit during the output of the RF circuit at each of the different operating frequencies; and
regulating an operating frequency of the RF circuit to the resonant frequency.

2. The operating frequency regulation method for the RF circuit of claim 1, wherein the RF circuit comprises an RF power supply, and controlling the RF circuit to output to the load at the different operating frequencies comprises:
controlling the RF power supply of the RF circuit to output to the load at least at a first operating frequency f₁ and a second operating frequency f₂.

3. The operating frequency regulation method for the RF circuit of claim 2, wherein detecting the circuit parameter of the RF circuit during the output of the RF circuit at each of the different operating frequencies comprises:
detecting a circuit parameter of the RF circuit during output of the RF circuit at each of the first operating frequency f₁ and the second operating frequency f₂.

4. The operating frequency regulation method for the RF circuit of claim 3, wherein calculating the resonant frequency of the RF circuit based on the detected circuit parameter of the RF circuit during the output of the RF circuit at each of the different operating frequencies comprises:
calculating an equivalent inductance L and an equivalent capacitance C of the RF circuit based on the detected circuit parameter of the RF circuit during the output of the RF circuit at each of the first operating frequency f₁ and the second operating frequency f₂; and
calculating the resonant frequency f₀ of the RF circuit according to the equivalent inductance L and the equivalent capacitance C.

5. The operating frequency regulation method for the RF circuit of claim 4, wherein detecting the circuit parameter of the RF circuit during the output of the RF circuit at each of the first operating frequency f₁ and the second operating frequency f₂ comprises:
detecting a first voltage value U₁ and a first current value I₁ of the RF circuit during output of the RF circuit at the first operating frequency f₁, a second voltage value U₂ and a second current value I₂ of the RF circuit during output of the RF circuit at the second operating frequency f₂, and a resistance R of the load;
wherein the first voltage value U₁ is an output voltage value U of the RF power supply during output of the RF power supply at the first operating frequency f₁, the second voltage value U₂ is an output voltage value U of the RF power supply during output of the RF power supply at the second operating frequency f₂, the first current value I₁ is a current value I of the RF circuit during the output of the RF circuit at the first operating frequency f₁, and the second current value I₂ is a current value I of the RF circuit during the output of the RF circuit at the second operating frequency f₂.

6. The operating frequency regulation method for the RF circuit of claim 5, wherein calculating the equivalent inductance L and the equivalent capacitance C of the RF circuit based on the detected circuit parameter of the RF circuit during the output of the RF circuit at each of the first operating frequency f₁ and the second operating frequency f₂ comprises:
calculating the equivalent inductance L and the equivalent capacitance C of the RF circuit, based on the first voltage value U₁ and the first current value I₁ of the RF circuit during the output of the RF circuit at the first operating frequency f₁, the second voltage value U₂ and the second current value I₂ of the RF circuit during the output of the RF circuit at the second operating frequency f₂, and the resistance R of the load.

7. The operating frequency regulation method for the RF circuit of claim 6, wherein calculating the equivalent inductance L and the equivalent capacitance C of the RF circuit, based on the first voltage value U₁ and the first current value I₁ of the RF circuit during the output of the RF circuit at the first operating frequency f₁, the second voltage value U₂ and the second current value I₂ of the RF circuit during the output of the RF circuit at the second operating frequency f₂, and the resistance R of the load comprises:
calculating the equivalent inductance L and the equivalent capacitance C of the RF circuit according to the following relational expressions:
a first relational expression: U₁=I₁(R+jX₁) and X₁=L*2πf₁−1/(C*2πf₁), where j is an imaginary unit, and X₁ is a reactance of the RF circuit during the output of the RF circuit at the first operating frequency f₁; and
a second relational expression: U₂=I₂(R+jX₂) and X₂=L*2πf₂−1/(C*2πf₂), where j is an imaginary unit, and X₂ is a reactance of the RF circuit during the output of the RF circuit at the second operating frequency f₂.

8. The operating frequency regulation method for the RF circuit of claim 7, wherein calculating the resonant frequency f₀ of the RF circuit according to the equivalent inductance L and the equivalent capacitance C comprises:
calculating the resonant frequency f₀ of the RF circuit according to the equivalent inductance L and the equivalent capacitance C using a relational expression f₀=1/(2π\sqrt{LC}).

9. An operating frequency control circuit, configured to regulate an operating frequency of a radio frequency (RF) circuit, and comprising:
a control unit configured to control the RF circuit to output to a load at different operating frequencies; and
a circuit parameter detection unit configured to detect a circuit parameter of the RF circuit during output of the RF circuit at each of the different operating frequencies;
wherein the control unit is further configured to calculate a resonant frequency of the RF circuit based on the detected circuit parameter of the RF circuit during the output of the RF circuit at each of the different operating frequencies, and control to regulate the operating frequency of the RF circuit to the resonant frequency.

10. A radio frequency (RF) power supply device, comprising an operating frequency control circuit and an RF circuit, wherein the operating frequency control circuit comprises:
a control unit configured to control the RF circuit to output to a load at different operating frequencies; and
a circuit parameter detection unit configured to detect a circuit parameter of the RF circuit during output of the RF circuit at each of the different operating frequencies;
wherein the control unit is further configured to calculate a resonant frequency of the RF circuit based on the detected circuit parameter of the RF circuit during the output of the RF circuit at each of the different operating frequencies, and control to regulate the operating frequency of the RF circuit to the resonant frequency;
wherein the operating frequency control circuit is configured to control operations in the operating frequency regulation method for the RF circuit in claim 1 to be performed to regulate an operating frequency of the RF circuit, and the RF circuit has a resonant frequency f₀ and comprises:
an RF power supply configured to output to a load at different operating frequencies; and
an RF output end configured to be connected to the load.

11. The RF power supply device of claim 10, wherein the RF circuit further comprises an inductor-capacitor network, the inductor-capacitor network comprises at least one equivalent inductor and at least one equivalent capacitor, and the at least one equivalent inductor and the at least one equivalent capacitor are connected in series or in parallel.

12. The RF power supply device of claim 11, wherein one end of the RF power supply is connected to one end of the RF output end or the inductor-capacitor network, and another end of the RF power supply is connected to a ground.
